(19) United States
(12) Patent Application Publication
(10) Pub. No.: US 2014/0190548 A1
(43) Pub. Date: Jul. 10, 2014

(54) SOLAR CELL, SOLAR CELL MODULE, AND METHOD FOR MANUFACTURING SOLAR CELL MODULE

(71) Applicant: Sanyo Electric Co., Ltd., Osaka (JP)

(72) Inventor: HIROYUKI KASE, Shiga (JP)

(73) Assignee: SANYO ELECTRIC CO., LTD., Osaka (JP)

(21) Appl. No.: 14/205,373

(22) Filed: Mar. 12, 2014

Related U.S. Application Data
(63) Continuation of application No. PCT/JP2011/072350, filed on Sep. 29, 2011.

(51) Int. Cl. H01L 31/05

(52) U.S. Cl. CPC H01L 31/05
USPC 136/244; 136/256; 29/592.1

(57) ABSTRACT

A solar module and a manufacturing method for a solar module with improved reliability are provided. The solar module includes a solar cell and a wiring member. A wiring member is connected electrically to the solar cell. The solar cell includes a photoelectric conversion unit, electrodes, and resin members. The electrodes are arranged on one main surface of the photoelectric conversion unit. The electrodes are connected electrically to the wiring member. The resin members are arranged on the one main surface in the area including an electrode and below the wiring member. The solar module also includes a resin adhesive layer. The resin adhesive layer bonds the wiring member to the surface of the solar cell including the surfaces of the resin members.

### BACKGROUND

1. Technical Field

The present technical field relates to a solar cell, a solar module, and a manufacturing method therefor.

2. Background Art

Solar modules including a plurality of solar cells connected to each other electrically using wiring members have attracted attention in recent years as an energy source with a low environmental impact. For example, a solar module is described in Patent Document 1 in which the solar cells and wiring members are bonded to each other using a resin adhesive.

### PRIOR ART DOCUMENTS

### Patent Documents

Patent Document 1: Japanese Patent unexamined Publication No. 2010-238938

### SUMMARY

### Problem to be Solved

There has been growing demand in recent years for solar modules that are more reliable.

### Means of Solving the Problem

A solar cell in one aspect of the present disclosure includes a photoelectric conversion unit, an electrode, and a resin member. The electrodes are arranged on one main surface of the photoelectric conversion unit. Wiring members are connected electrically to the electrode. The resin members are arranged in the area including the electrode and positioned below the wiring members.

The solar cell in another aspect of the present disclosure includes a photoelectric conversion unit and an electrode. The electrode is arranged on one main surface of the photoelectric conversion unit. The electrode includes a plurality of finger portions and busbar portions. The solar cell in another aspect of the present disclosure also includes resin members arranged inside the area of the busbar portion on the one main surface.

The solar module in one aspect of the present disclosure includes solar cells and wiring members. The wiring members are connected electrically to the solar cells. Each solar cell includes a photoelectric conversion unit, an electrode, and resin members. The electrodes are arranged on one main surface of the photoelectric conversion unit. The electrodes are connected electrically to the wiring members. The resin members are each arranged on one main surface in an area including the electrode and positioned below the wiring members. The solar module also includes a resin adhesive layer. The resin adhesive layer bonds the wiring members to the surface of the solar cell including the surface of the resin member.

The present disclosure is also a method for manufacturing a solar module including the steps of: preparing a solar cell having a photoelectric conversion unit, an electrodes arranged on the one main surface of the photoelectric conversion unit, and resin members which are arranged inside areas including the electrode on the one main surfaces of the photoelectric conversion unit; and bonding the wiring members to the surfaces of the solar cell including the surface of the resin member using a resin adhesive to electrically connect the electrodes and the wiring members.

### Effect of the Disclosure

The present disclosure is able to provide a more reliable solar module.

### BRIEF DESCRIPTION OF DRAWINGS

FIG. 1 is a simplified cross-sectional view of the solar module in the first embodiment.

FIG. 2 is a simplified plan view of a solar cell in the first embodiment.

FIG. 3 is a simplified rear view of a solar cell in the first embodiment.

FIG. 4 is a simplified partial cross-sectional view of the solar module from line IV-IV in FIG. 2.

FIG. 5 is a simplified cross-sectional view used to explain the method for manufacturing the solar module in the first embodiment.

FIG. 6 is a simplified partial cross-sectional view of the solar module in the second embodiment.

FIG. 7 is a simplified plan view of a solar cell in the third embodiment.

FIG. 8 is a simplified plan view of a solar cell in the fourth embodiment.

FIG. 9 is a simplified plan view of a solar cell in the fifth embodiment.

FIG. 10 is a simplified rear view of a solar cell in the sixth embodiment.

FIG. 11 is a simplified plan view of the sample manufactured in the first test example.

FIG. 12 is a simplified plan view of the sample manufactured in the second test example.

### DETAILED DESCRIPTION OF PREFERRED EMBODIMENTS

The following is an explanation of examples of preferred embodiments. The following embodiments are merely examples. The present invention is not limited by the following embodiments in any way.

Further, in each of the drawings referenced in the embodiments, members having substantially the same function are denoted by the same symbols. The drawings referenced in the embodiments are also depicted schematically. The dimensional ratios of the objects depicted in the drawings may differ from those of the actual objects. The dimensional ratios of objects may also vary between drawings. The specific dimensional ratios of the objects should be determined with reference to the following explanation.

### 1st Embodiment

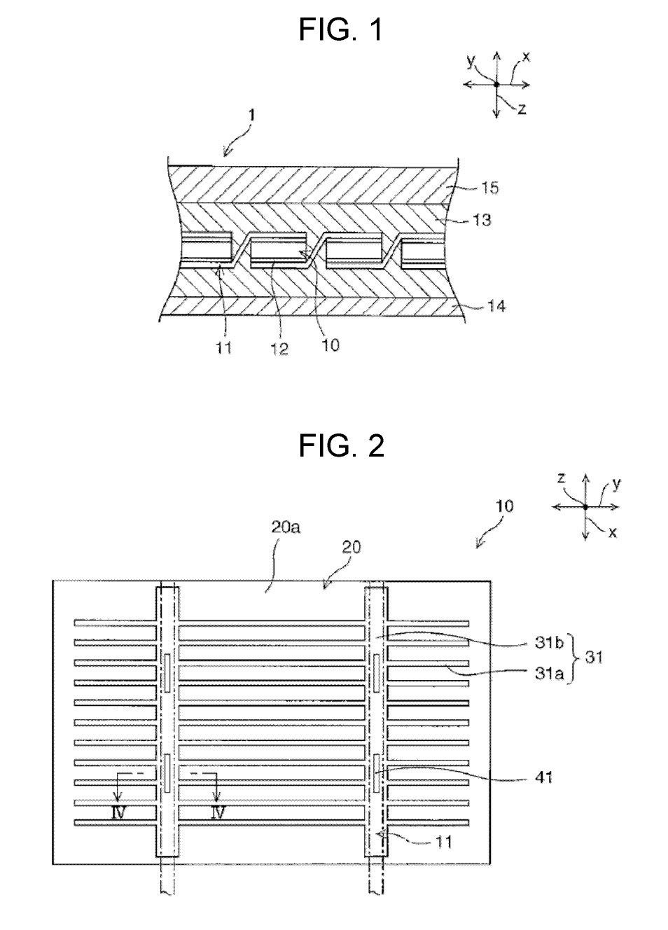

As shown in FIG. 1, the solar module 1 includes a plurality of solar cells 10. The solar cells 10 are connected electrically via a wiring member 11. The wiring member 11 and solar cells 10 are bonded via an adhesive layer 12. The method used to bond the wiring member 11 and solar cells 10 is described in greater detail below.

The solar cells 10 are provided inside a bonding layer 13 filling the space between a first protecting member 14 and a second protecting member 15. The second protecting member 15 is provided on the side of the solar cells 10 which is exposed to light. The second protecting member 15 can be composed of a transparent member such as a transparent glass plate or plastic sheet. The first protecting member 14 is provided on the back surface side of the solar cells 10. The first protecting member 14 can be composed of resin film or resin film containing interposed metal foil. The bonding layer 13 can be composed of a resin such as an ethylene/vinyl acetate (EVA) copolymer or polyvinyl butyral (PVB).

If necessary, a frame may be mounted on the peripheral portion of the solar module 1. A terminal box may also be provided on the surface of the first protecting member 14 to draw output to the outside.

As shown in FIG. 2 through FIG. 4, each solar cell 10 includes a photoelectric conversion unit 20. The photoelectric conversion unit 20 generates carriers such as electrons or holes when exposed to light.

The photoelectric conversion unit 20 has a first main surface 20a positioned on the second protecting member 15 side and a second main surface 20b positioned on the first protecting member 14 side. The first main surface 20a composes the light-receiving surface of the solar cells 10. The second main surface 20b composes the back surface of the solar cells 10.

The first electrode 31 is arranged on the first main surface 20a. The second electrode 32 is arranged on the second main surface 20b. Either the first electrode 31 or the second electrode 32 is the electrode that collects the minority carrier, and the other one is the electrode that collects the majority carrier. At least a portion of the first electrode 31 is arranged so as to overlap with the wiring member 11 in the thickness direction z. Similarly, at least a portion of the second electrode 32 is arranged so as to overlap with the wiring member 11 in the thickness direction z. Both the first electrode 31 and the second electrode 32 are connected electrically to the wiring member 11.

As shown in FIG. 2, the first electrode 31 includes a plurality of finger portions 31a and a plurality of busbar portions 31b. The finger portions 31a extend parallel to each other in one direction (the y-direction). The finger portions 31a are also arranged parallel to each other at a predetermined interval in the direction (the x-direction) orthogonal to the one direction. The finger portions 31a are connected electrically to a busbar portion 31b. The busbar portions 31b are arranged so as to extend in the x-direction.

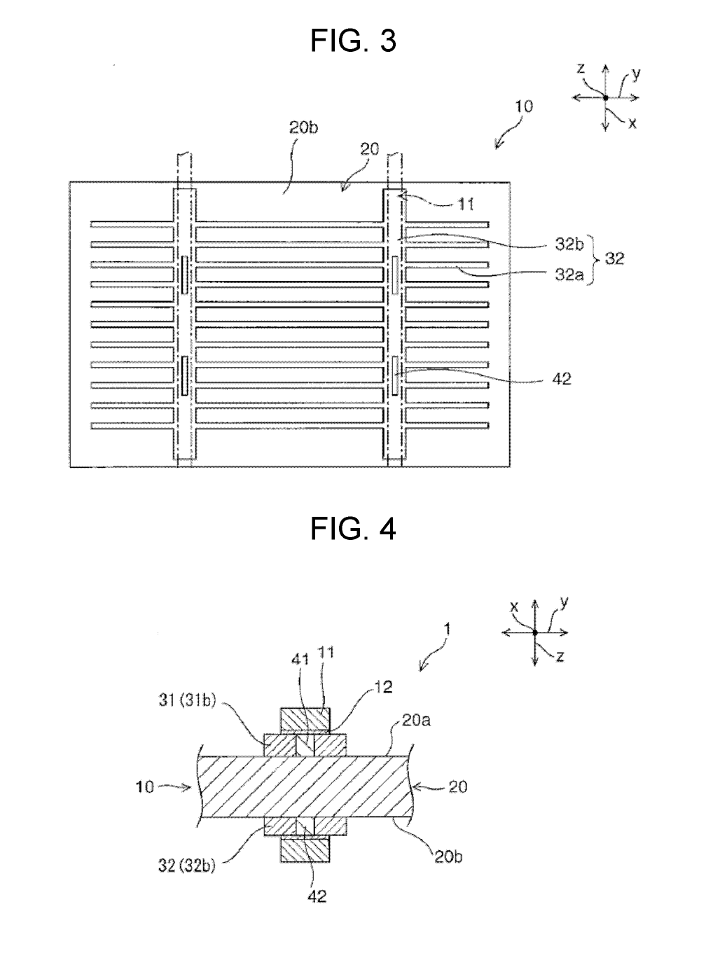

As shown in FIG. 3, the second electrode 32 includes a plurality of finger portions 32a and a plurality of busbar portions 32b. The finger portions 32a extend parallel to each other in the y-direction. The finger portions are also arranged parallel to each other at a predetermined interval in the x-direction orthogonal to the one direction. The finger portions 32a are connected electrically to a busbar portion 32b. The busbar portions 32b are arranged so as to extend in the x-direction.

In the explanation of the example of the present embodiment, the busbar portions 31b, 32b are wider than the wiring member 11. However, the busbar portions may be thinner than the wiring member, or substantially the same width as the wiring member.

The first electrode 31 arranged on the first main surface 20a, or the light-receiving surface, preferably has a smaller surface area than the second electrode 32 in order to reduce light reception loss.

In the explanation of the example of the present embodiment, both the first electrode 31 and the second electrode 32 have a plurality of finger portions 31a, 32a and busbar portions 31b, 32b. However, there are no particular restrictions on the shape of the first electrode 31 and the second electrode 32. Either the first electrode 31 or the second electrode 32 may be a so-called busbar-less electrode having only finger portions. The second electrode 32 may be a thin-film electrode arranged substantially over the entire surface of the second main surface 20b.

A resin member 41 is arranged on the first main surface 20a of the photoelectric conversion unit 20 in the area including the first electrode 31 and beneath the wiring member 11. A resin member 42 is also arranged on the second main surface 20b of the photoelectric conversion unit in the area including the second electrode 32 and beneath the wiring member 11.

The resin member 41 has substantially the same thickness as the busbar portions 31b. The resin member 42 has substantially the same thickness as the busbar portions 32b. The wiring member 11 is bonded to the main surfaces of the solar cell 10 including the resin members 41, 42 using a resin adhesive layer 12. More specifically, in the present embodiment, the wiring member 11 is bonded by the resin adhesive layer 12 to at least some of the surface of the busbar portions 31b and to at least some of the surface of resin member 41. The wiring member 11 is bonded by the resin adhesive layer 12 to at least some of the surface of the busbar portions 32b and to at least some of the surface of resin member 42.

The resin adhesive layer 12 may contain a cured resin adhesive. The resin adhesive layer 12 may also contain a plurality of conductive members and a cured resin adhesive. When the resin adhesive layer 12 does not contain conductive members, there needs to attached directly between at least some of the wiring member 11 and the electrodes 31, 32. When the resin adhesive layer 12 contains conductive members, an electrical connection may be established via direct contact between the wiring member 11 and the electrodes 31, 32, or an electrical connection may be established via the conductive members.

There are no particular restrictions on the configuration of the wiring member 11. The wiring member 11 can be composed of a suitable conductive material, including metals such as Cu or Ag, or alloys containing these metals. The wiring member 11 may have a coating layer containing a conductive material such as solder. The wiring member 11 may also have an uneven surface.

As shown in FIG. 2, a plurality of resin members 41 may be provided at intervals in the x-direction, or the direction in which both the wiring member 11 and the busbar portions 31b extend, in each area including a busbar portion 31b. The resin members 41 are surrounded by busbar portions 31. A plurality of resin members 41 is not provided in the end portion of the busbar portion 31b in the x-direction. The length of each resin member 41 in the x-direction may be longer, shorter or equal to the pitch of the finger portions 31a in the x-direction.

As shown in FIG. 3, a plurality of resin members 42 may be provided at intervals in the x-direction, or the direction in which both the wiring member 11 and the busbar portions 32b extend, in each area including a busbar portion 32b. The resin members 42 are surrounded by busbar portions 32. A plurality of resin members 42 is not provided in the end portion of the busbar portion 32b in the x-direction. The length of each resin member 42 in the x-direction may be longer, shorter or equal to the pitch of the finger portions 32a in the x-direction.

The wiring member 11 is bonded via the resin adhesive layer 12 to the surfaces of the solar cells 10 including the surfaces of the resin members 41, 42. The bonding strength of the wiring member 11 to the solar cells 10 is increased by bonding the resin members 41, 42 to the resin adhesive layer 12. The result is a solar module 1 with improved reliability.

In the solar module 1, the wiring member 11 and resin member 41 are bonded in several spots in the x-direction, and the wiring member 11 and resin member 42 are bonded in several spots in the x-direction. Because there are several areas in the extension direction of the wiring member 11 in which the bonding strength of the wiring member 11 and the solar cells 10 has been improved, a solar module 1 can be obtained with even better reliability.

In the solar module 1, the resin member 41 is surrounded by busbar portions 31b. In this way, the bonding strength of the electrical connection between the wiring member 11 and the busbar portions 31b is improved near the areas where the wiring member 11 and the resin member 41 have been bonded with greater bonding strength. This suppresses any decrease in electrical connection properties between the wiring member 11 and busbar portions 31b. This also suppresses any decrease in electrical connection properties between the wiring member 11 and busbar portions 32b. The result is a solar module 1 with even better reliability.

In the solar module 1, the busbar portions 31b are arranged below the wiring member 11 whose bonding strength to the solar cell 10 has been improved by the resin member 41. The resin member 41 acts to prevent the busbar portions 31b from peeling away from the first main surface 20a of the photoelectric conversion unit 20. This suppresses any deterioration in the electrical connection properties between the busbar portions 31b and the first main surface 20a of the photoelectric conversion unit 20 even when force is applied in a direction that would cause the wiring member 11 to peel off. This also suppresses any deterioration in electrical connection properties between the busbar portions 32b and the second main surface 20b of the photoelectric conversion unit. The result is a solar module 1 with even better reliability. Because the reliability of solar modules including solar cells having busbar portions 31b, 32b formed using a plating method can be improved, the industrial effects are especially advantageous.

From the standpoint of improving the bonding strength between the wiring member 11 and the solar cells 10, the resin members 41, 42 are preferably composed of at least one type of resin selected from a group including polyester resins, ethylene/vinyl acetate copolymers, acrylic resins, epoxy resins and urethane resins, and the resin adhesive layer 12 preferably includes at least one type of cured resin adhesive selected from a group including EVA resins, acrylic resins, epoxy resins and urethane resins. The resin members 41, 42 are more preferably composed of at least one type of resin selected from a group including acrylic resins and epoxy resins, and the resin adhesive layer 12 more preferably includes at least one type of cured resin adhesive selected from a group including acrylic resins and epoxy resins.

The following is an explanation of an example of a method for manufacturing a solar module 1.

### Solar Cell Manufacturing Step

First, a photoelectric conversion unit 20 is prepared. The photoelectric conversion unit 20 can be prepared using any method well known in the art.

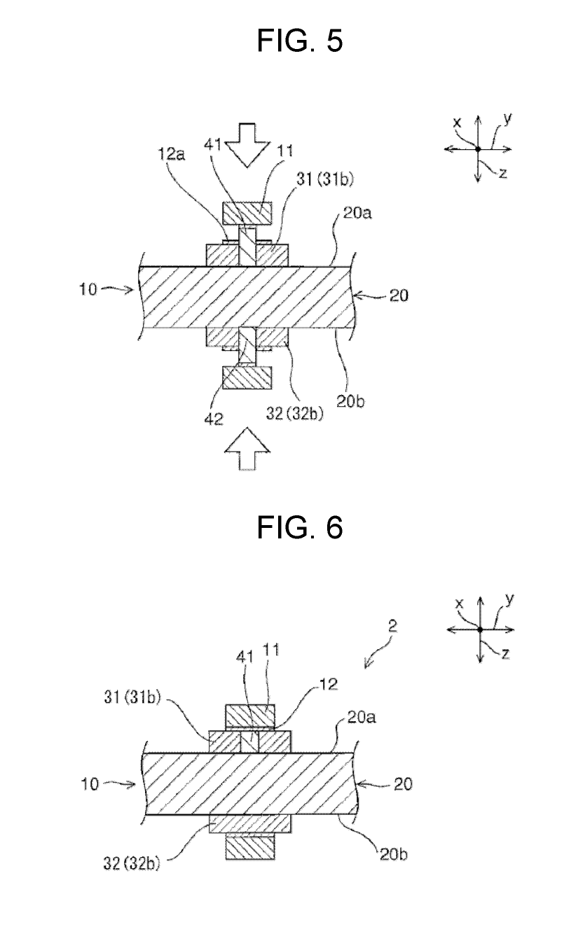

Next, as shown in FIG. 5, a resin member 41 is formed on the first main surface 20a of the photoelectric conversion unit 20, and a resin member 42 is formed on the second main surface 20b. The resin members 41, 42 can be created by forming a resist film to cover all but the portion in which the resin members 41, 42 are to be formed, forming a resin film on the resist film, and then lifting off the resist film. Alternatively, a resin layer may be formed substantially over the entire first main surface 20a, and then removing the resin layer except for the portions in which the resin members 41, 42 remain. This step can be performed using photolithography.

Next, the first electrode 31 and the second electrode 32 are formed to complete the solar cell 10. The first electrode 31 and the second electrode 32 can be formed using a method such as screen printing.

When resin member 41 is formed, a resin layer may be formed substantially over the entire first main surface 20a, and then the resin layer may be removed only in the areas where the electrode 31 is to be formed. In this case, the remaining resin layer serves as a mask, making the formation of the first electrode 31 easier using the plating method. Resin member 42 can be formed in the same way.

### Connection Step

Next, a plurality of solar cells 10 created in this way are provided and connected electrically using a wiring member 11. More specifically, the wiring member 11 is bonded via a resin adhesive 12a to the surface of a solar cell 10 including the resin member 41, and the wiring member 11 is bonded via resin adhesive 12a to the back surface of the solar cell 10 including the surface of resin member 42. This step is repeated to electrically connect a plurality of solar cells 10 using a wiring member 11.

Afterwards, the plurality of solar cells 10 connected electrically via a wiring member 11 are sealed using a bonding layer 13 between a first protecting member 14 and a second protecting member 15. More specifically, a resin sheet such as an EVA sheet is placed on top of the second protecting member 15. The solar cells 10 are placed on this resin sheet. A resin sheet such as an EVA sheet is placed on this, and a first protecting member 14 is placed on top of this. Heat can be applied in a reduced pressure environment to bond and laminate these layers and complete the solar module 1.

When the solar cells 10 are prepared, there are no particular restrictions on the relationship between the thickness of resin member 41 and the electrode 31. However, as shown in FIG. 5, the resin member 41 is preferably thicker than the electrode 31. Similarly, there are no particular restrictions on the relationship between the thickness of resin member 42 and the electrode 32. However, the resin member 42 is preferably thicker than the electrode 32. In the connection step, pressure is preferably applied to the wiring member 11 and the solar cells 10 to bring them closer together with resin adhesive 12a between the wiring member 11 and the surface of the solar cell 10 including the surface of the resin member 41. This allows the resin adhesive 12a to harden while allowing the resin member 41 to become deformed. Similarly, pressure is preferably applied to the wiring member 11 and the solar cells 10 to bring them closer together with resin adhesive 12a between the wiring member 11 and the surface of the solar cell 10 including the surface of the resin member 42. This allows the resin adhesive 12a to harden while allowing the resin member 42 to be deformed.

In this way, the stress applied between the wiring member 11 and the solar cells 10 can be relaxed by the deformation of the resin members 41, 42. In other words, the application of a large amount of stress on the solar cells can be suppressed. As a result, damage to the solar cells 10 can be suppressed, and the yield of solar modules 1 can be increased.

Heat is preferably applied while the wiring member 11 and the solar cells 10 are being bonded. This makes the resin members 41, 42 more likely to become deformed during the connection step. Therefore, the application of a large amount of stress to the solar cells 10 can be effectively suppressed, and damage to the solar cells 10 can be more effectively suppressed.

From this standpoint, resin member 41 and resin member 42 are preferably arranged so as to partially overlap in plan view. Because this suppresses even more the application of a large amount of stress to the solar cells during the connection step, the yield of solar modules 1 can be increased.

The wiring member 11 is preferably bonded to one main surface of a solar cell 10 at the same time the wiring member 11 is bonded to the other main surface, but this can also be performed separately. This can further reduce the amount of stress applied to the solar cells 10, and can also suppress warping of the solar cells 10 due to the difference in the thermal expansion coefficients of the wiring member 11 and the solar cell 10.

The following is an explanation of additional examples of preferred embodiments. In the following explanation, components with substantially the same functions as those in the first embodiment are denoted by the same reference numbers, and further explanation of these components has been omitted.

### 2nd Embodiment

In the explanation of the example of the first embodiment, a resin member 41, 42 was provided on both sides of the solar cell 10. In the solar module 2 of the second embodiment, as shown in FIG. 6, a resin member 41 is provided on the light-receiving surface side of the solar cell 10 but a resin member is not provided on the back surface side. However, even this configuration is able to increase the bonding strength between the wiring member 11 and solar cells 10 and thus improve reliability.

A resin member 41 may be provided only on the back surface side of the solar cell 10, but the resin member 41 is preferably provided on the light-receiving side when the first electrode 31 on the light-receiving surface side has a smaller surface area than the second electrode 32 on the back surface side. This is able to reduce the large amount of stress on the first electrode 31 caused by the application of pressure on the wiring member 11 during the connection step.

### 3rd Embodiment

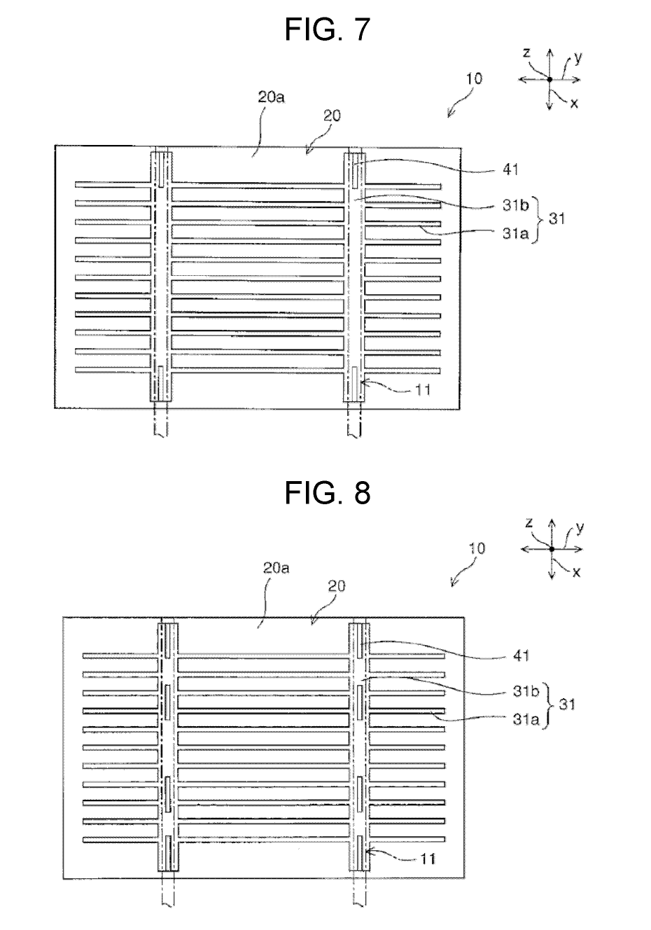

In the explanation of the example of the first embodiment, the resin members 41, 42 are not provided in the area including the ends of the busbar portions 31b, 32b in the x-direction, which is the direction in which the wiring member 11 extends. However, in the solar module of the third embodiment, as shown in FIG. 7, the resin members 41, 42 are provided in the area including the ends of the busbar portions 31b, 32b in the x-direction, which is the direction in which the wiring member 11 extends. This increases the bonding strength of the end portions to the solar cells 10, which is where peeling of the wiring member 11 starts. This is able to more effectively prevent peeling of the wiring member 11.

### 4th Embodiment

In the fourth embodiment, as shown in FIG. 8, the resin members 41, 42 include the area in which the ends of the busbar portions 31b, 32b in the x-direction, and a plurality of these members are provided at intervals over the entire busbar portions 31b, 32b in the length direction. This is able to more effectively prevent peeling of the wiring member 11.

### 5th Embodiment

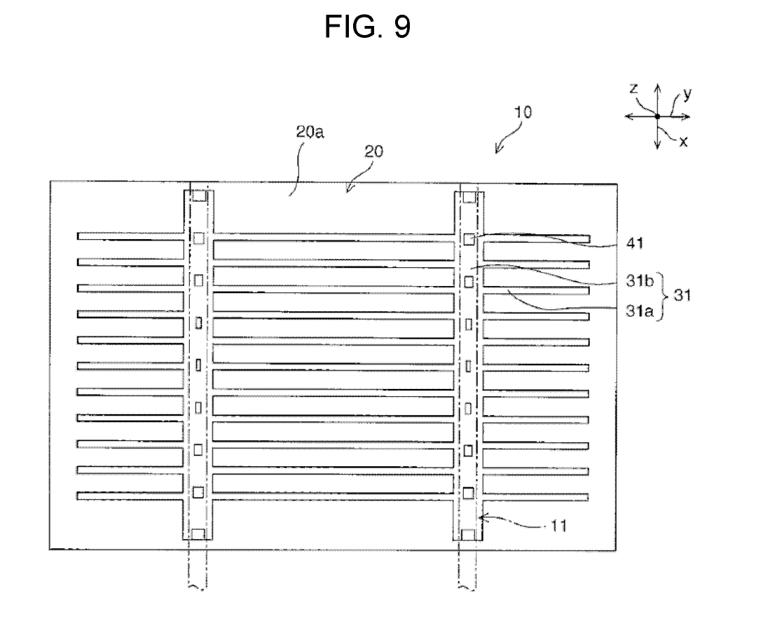

In the explanation of the example in the first embodiment, the resin members 41 have substantially the same shape, and the resin members 42 have substantially the same shape. However, in the fifth embodiment, as shown in FIG. 9, the surface areas of the resin members 41 increase as the resin members 41 get closer to the end of the photoelectric conversion unit 20 in the x-direction, which is the direction in which the wiring member 11 extends. Also, the length dimension of the resin members 41 becomes greater in the y-direction, or the width direction of the wiring member 11, as the resin members 41 get closer to the end portion in the x-direction. Similarly, the surface areas of the resin members 42 increase as the resin members 42 get closer to the end of the photoelectric conversion unit 20 in the x-direction, which is the direction in which the wiring member 11 extends. Also, the length dimension of the resin members 42 becomes greater in the y-direction, or the width direction of the wiring member 11, as the resin members 42 get closer to the end portion in the x-direction. In this way, the contact surface area between the electrodes 31, 32 and the wiring member 11 increases, and the bonding strength at the end portion of the wiring member 11, which is more likely to peel, can be increased.

### 6th Embodiment

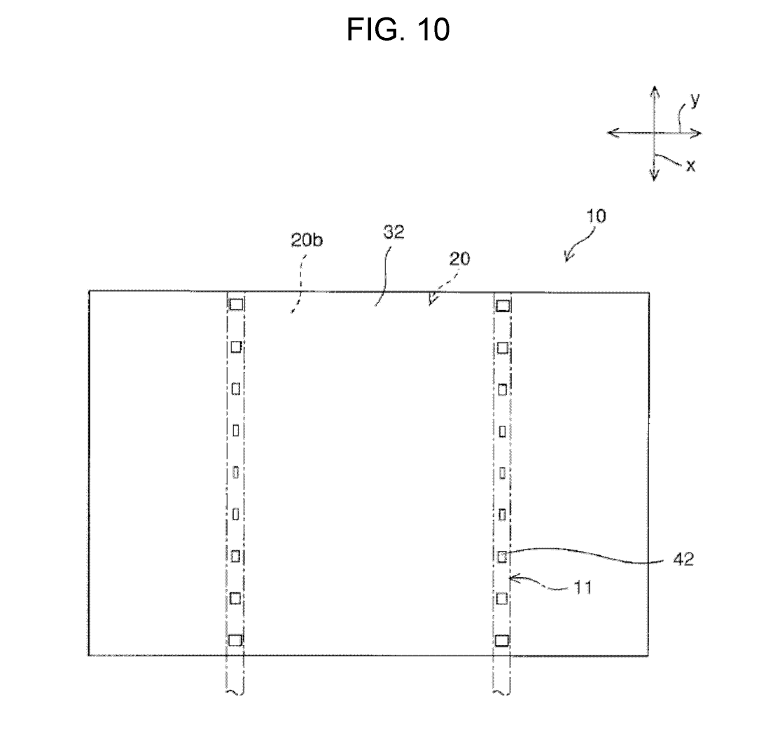

In the explanation of the example of the first embodiment, each of the first and second electrodes 31, 32 has a plurality of finger portions 31a, 32a, and busbar portions 31b, 32b connected to these electrically. However, in the sixth embodiment, as shown in FIG. 10, the second electrode 32 on the back surface side has a planar shape, and the first electrode 31 has a plurality of finger portions 31a and a busbar portion 31b. However, even this configuration is able to increase the bonding strength of the wiring member 11 to the solar cells 10 and realize improved reliability.

There are no particular restrictions on the method used to form the planar shaped second electrode 32. The second electrode 32 can be formed using a screen printing method, a plating method, a vapor deposition method, or a sputtering method.

A terminal portion may also be provided on the planar shaped second electrode 32 and bonded to the wiring member 11.

The following is a more detailed explanation of the present disclosure with reference to specific test examples. However, the present invention is not restricted in any way to these test examples. Various changes and improvements are possible without departing from the spirit and scope of the present disclosure.

### Test Example 1

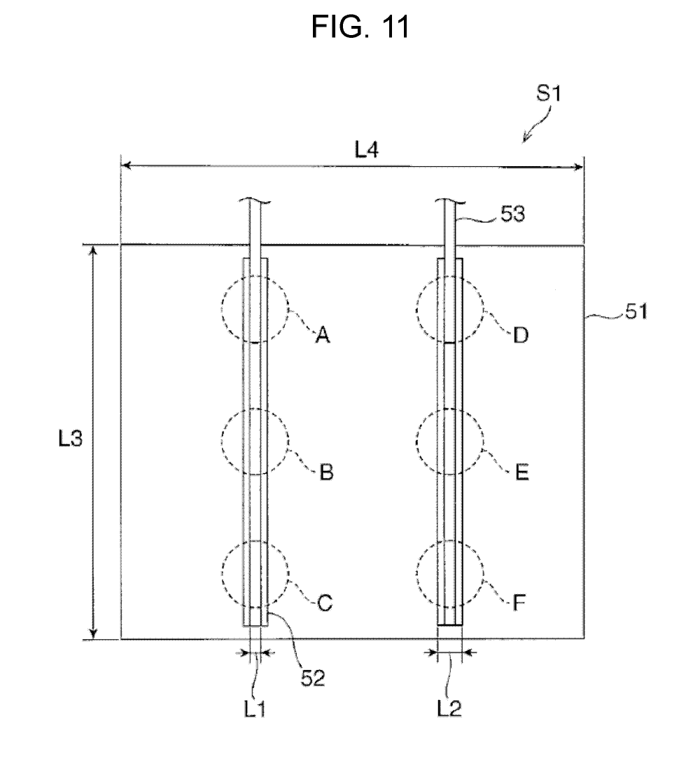

First, as shown in FIG. 11, a linear shaped electrode 52 made of a Ni—Cu—Ni laminate was formed using a plating method on a square photoelectric conversion unit 51 with a length (L3) of 104 mm and a width (L4) of 104 mm. The portion of the surface of the photoelectric conversion unit 51 not including the electrode 52 consisted of an acrylic resin layer. The width (L2) of the electrode 52 was 3 mm. A linear wiring member 53 made of Cu with a solder coating was affixed to the electrode 52 using a resin adhesive to complete two samples S1 in the first test example. The width (L1) of the wiring 53 was 1.2 mm. The wiring member 53 was affixed to the center of the electrode 52 in the width direction. In this way, the entire electrode 52 was bonded to the wiring member 53.

### Test Example 2

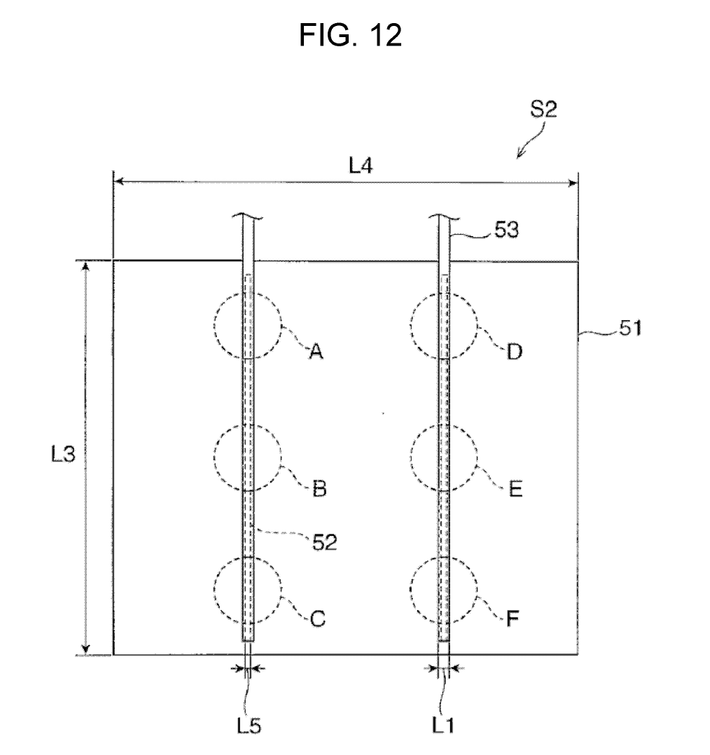

Two of the samples S2 for the second test example shown in FIG. 12 were prepared in the same manner as the first test example except that the width (L5) of the electrode 52 was 1.0 mm. In sample S2, 0.1 mm of the wiring member 53 protruded from both ends of the electrode 52, and were bonded directly to the acrylic resin layer constituting the surface layer of the photoelectric conversion unit 51. As a result, 83% of the surface area of the wiring member 53 was bonded to the electrode and 17% was bonded to the resin layer.

### Evaluation

An end of the wiring member 53 of each sample S1, S2 prepared in the first and second test examples was pulled at a 90-degree angle with respect to the plane direction of the photoelectric conversion unit 51 and a portion of the wiring member 53 was peeled. The strength at this time was measured at the six points (A-F) shown in FIG. 11 and FIG. 12, and the values were averaged to calculate the average peel strength. The results are shown below.

Average Peeling Strength in First Test Example: 0.4 N

Average Peeling Strength in Second Test Example: 1.2 N

It is clear from the results that the bonding strength of the wiring member can be improved by bonding a portion of the wiring member to a resin member.

The present disclosure includes many different embodiments not described herein. For example, a resin member may be provided which spans the entire busbar portion in the length direction.

Either one of the first and second electrodes may be a busbarless electrode composed of a plurality of finger portions without a busbar portion.

The busbar portion may be provided in a zigzag pattern.

The present disclosure includes many other embodiments not described herein. Therefore, the technical scope of the present disclosure is defined solely by the items of the disclosure specified in the claims pertinent to the above explanation.

What is claimed is:

1. A solar cell comprising:
a photoelectric conversion unit;
an electrode arranged on one main surface of the photoelectric conversion unit and connected electrically to wiring members; and
a resin member which is arranged in an area that the electrode is arranged in and that is positioned below the wiring members.

2. A solar cell comprising:
a photoelectric conversion unit; and
an electrode arranged on one main surface of the photoelectric conversion unit;
the electrodes including a plurality of finger portions and busbar portions; and
a resin member arranged in the area of the busbar portions on the one main surface.

3. The solar cell according to claim 2, wherein the busbar portions extend in one direction, and
the resin member includes a plurality of resin members arranged in the extending direction of the busbar portion.

4. The solar cell according to claim 3, wherein the plurality of resin members includes a resin member arranged in an end portion area in the extending direction of the busbar portions.

5. The solar cell according to claim 3, wherein the plurality of resin members includes a resin member on the end in the extending direction of the busbar portions having a surface area greater than the resin members arranged on the inside.

6. The solar cell according to claim 3, wherein the plurality of resin members includes a resin member on the end in the extending direction of the busbar portion having a length dimension in the width direction greater than the resin members arranged on the inside.

7. The solar cell according to claim 2 further comprising electrodes including a plurality of finger portions and busbar portions, and resin members arranged inside the area of the busbar portions;
a resin member on the one main surface and a resin member on the other main surface being arranged in positions which are partially overlapping in plan view.

8. A solar module comprising:
solar cells,
and wiring members electrically connected to the solar cells;
each solar cell including:
a photoelectric conversion unit;
an electrode arranged on one main surface of the photoelectric conversion unit and connected electrically to the wiring members, and
a resin member on the one main surface which is arranged in an area that the electrode is arranged in and that is positioned below the wiring members;
a resin adhesive layer being further provided to bond the wiring members to the surface of the solar cell including the surface of the resin member.

9. The solar module according to claim 8 further comprising a plurality of resin members arranged in the extending direction of the wiring members.

10. The solar module according to claim 9, wherein the electrode has
a plurality of finger portions, and
busbar portions connected electrically to the finger portions and connected electrically to the wiring members; and
the plurality of resin members include a resin member arranged in the area including the busbar portions.

11. A method for manufacturing a solar module comprising the steps of:
preparing solar cells having a photoelectric conversion unit, an electrode arranged on the one main surface of the photoelectric conversion unit, and a resin member arranged inside an area including the electrode on the one main surface of the photoelectric conversion unit; and
bonding the wiring member to the surface of the solar cells including the surface of the resin member using a resin adhesive to electrically connect the electrode and the wiring members.

12. The method for manufacturing a solar module according to claim 11, wherein the resin member is formed to a greater thickness than the electrode in the preparation step; and
pressure is applied to bring the wiring member and the solar cell closer together with the resin adhesive interposed between the wiring members and the surface of the solar cell including the surface of the resin member to cure the resin adhesive while allowing the resin member to become deformed in the connection step.

13. The method for manufacturing a solar module according to claim 12, wherein heat is applied while bonding the wiring members and the solar cell in the connection step.
